(19) United States
(12) Patent Application Publication
(10) Pub. No.: US 2024/0128386 A1
(43) Pub. Date: Apr. 18, 2024

(54) PHOTODETECTOR

(71) Applicant: HAMAMATSU PHOTONICS K.K., Hamamatsu-shi, Shizuoka (JP)

(72) Inventor: Wei DONG, Hamamatsu-shi, Shizuoka (JP)

(73) Assignee: HAMAMATSU PHOTONICS K.K., Hamamatsu-shi, Shizuoka (JP)

(21) Appl. No.: 18/243,753

(22) Filed: Sep. 8, 2023

(30) Foreign Application Priority Data
Oct. 13, 2022 (JP) 2022-164866

(51) Int. Cl. H01L 31/0236; H01L 31/0216; H01L 31/0224

(52) U.S. Cl. CPC H01L 31/02363; H01L 31/02161; H01L 31/022408

(57) ABSTRACT

A photodetector includes a first conduction-type semiconductor layer, a semiconductor light absorption layer provided on the first conduction-type semiconductor layer, and a second conduction-type semiconductor layer provided on the semiconductor light absorption layer. Inside the semiconductor light absorption layer, finely modified portions forming a localized inhomogeneous electric field inside the semiconductor light absorption layer by scattering incident light are provided in a manner of being separated from the second conduction-type semiconductor layer.

### TECHNICAL FIELD

The present disclosure relates to a photodetector.

### BACKGROUND

In recent years, remarkable progress has been made in laser sensing technology used for autonomous driving functions and collision prevention functions of vehicles. Along with this, there is a demand for development of inexpensive and high-performance photodetectors for an infrared region. For example, for a shortwave infrared (SWIR) band having a wavelength of 1.3 μm or longer, semiconductor light receiving elements having an InGaAs substrate are mainly used. However, high-performance array-type photodetectors using this substrate have a cost problem.

Against such a background, regarding photodetectors which do not depend on InGaAs, photodetectors utilizing a localized inhomogeneous electric field inside a light absorption layer have been developed. In photodetectors of this type, in place of InGaAs, a relatively inexpensive material such as Si or Ge, for example, is utilized for a light absorption layer. Since such materials are indirect transition semiconductors, there is a problem that sensitivity will deteriorate in the vicinity of a band edge wavelength band. Regarding such a problem, a technology in which a constitution for generating a localized inhomogeneous electric field in response to incidence of light is provided near a semiconductor light absorption layer to achieve improvement in sensitivity by means of electric-field enhancement due to optical confinement is being studied. Another effect of a localized inhomogeneous electric field is that a large wavenumber can be imparted to electrons inside a semiconductor based on the uncertainty principle. Due to this effect, it is conceivable that direct optical transition is able to be realized with an indirect transition semiconductor material, which also contributes to improvement in absorption of light.

Examples of a photodetector utilizing electric-field enhancement by a localized inhomogeneous electric field include the light receiving element disclosed in PCT International Publication No. WO2009/088071. In this light receiving element in the related art, a first conduction-type semiconductor layer, a non-doped-type semiconductor light absorption layer, a second conduction-type semiconductor layer, and a conductive layer are provided on a substrate in this order. A laminate of the conductive layer, the second conduction-type semiconductor layer, and the non-doped-type semiconductor light absorption layer is provided with a plurality of openings which are regularly arrayed. The openings have a width equal to or shorter than a wavelength of incident light and are provided such that they penetrate the conductive layer and the second conduction-type semiconductor layer and reach the non-doped-type semiconductor light absorption layer.

In addition, for example, the light receiving element disclosed in United States Patent Application, Publication No. 2009/0134486 has a semiconductor layer, and a pair of metal electrodes which are disposed on a front surface of the semiconductor layer with a predetermined gap d therebetween and form an MSM junction. When a wavelength of incident light is λ, the gap between the pair of metal electrodes satisfies a relationship of λ>d. At least one of the pair of metal electrodes forms a Schottky junction with the semiconductor layer and is embedded into the semiconductor layer to a position at a depth smaller than λ/(2n) when an index of refraction of the semiconductor layer is n.

### SUMMARY

The detection sensitivity of a photodetector utilizing electric-field enhancement by a localized inhomogeneous electric field is still inferior to that of a photodetector utilizing InGaAs. On the other hand, when the same localized inhomogeneous electric field is utilized, it is conceivable to adopt a technique of realizing direct transition by imparting a large wavenumber to electrons inside a semiconductor based on the uncertainty principle. Regarding improvement in sensitivity of a photodetector based on this principle, there is a need to sufficiently secure a wavenumber component of a localized inhomogeneous electric field in a semiconductor light absorption layer. The effect of a localized inhomogeneous electric field is quickly attenuated due to increase in distance between a generation position of the localized inhomogeneous electric field and a position of a depletion layer in a semiconductor light absorption layer. In the light receiving element disclosed in PCT International Publication No. WO2009/088071, the generation position of a localized inhomogeneous electric field is in the vicinity of a boundary surface between a conductive layer and a second conduction-type semiconductor layer, but the generation position is separated from a non-doped-type semiconductor light absorption layer by an amount corresponding to a thickness of the second conduction-type semiconductor layer. For this reason, it is considered difficult to achieve improvement in sensitivity of a photodetector based on the principle by applying the structure in PCT International Publication No. WO2009/088071.

In the light receiving element disclosed in United States Patent Application, Publication No. 2009/0134486, improvement in detection sensitivity is achieved by embedding a metal electrode into a semiconductor layer. However, since the semiconductor layer having a generation position of a localized inhomogeneous electric field and a photocurrent extraction electrode are integrated, there is a problem that a dark current caused by a Schottky junction will become relatively large. For this reason, in the light receiving element disclosed in United States Patent Application, Publication No. 2009/0134486, there is a problem that it will be difficult to improve an SN ratio.

The present disclosure has been made in order to resolve the foregoing problems, and an object thereof is to provide a photodetector in which detection sensitivity can be improved while occurrence of a dark current is curbed.

In order to resolve the foregoing problems, the inventors of this application have focused on the generation source of the localized inhomogeneous electric field. As described above, the effect of the localized inhomogeneous electric field is quickly attenuated due to increase in distance between the generation position of the localized inhomogeneous electric field and the position of a depletion layer in the semiconductor light absorption layer. Regarding a technique of causing the generation position of a localized inhomogeneous electric field and the position of the depletion layer in the semiconductor light absorption layer to coincide with or be close to each other, for example, it is conceivable to adopt a structure in which openings are provided in a semiconductor layer by etching and metal structures serving as generation sources of the localized inhomogeneous electric field are disposed inside the openings.

However, when processing by etching is performed from a front surface of a semiconductor light absorption layer to the position of a depletion layer, it is conceivable that many defects of a semiconductor layer caused by etching will occur near the position of the depletion layer, resulting in increase in dark current. Particularly, it is conceivable that parts not in contact with metal structures on inner wall surfaces of openings cause increase in dark current although they do not contribute to generation of a localized inhomogeneous electric field (that is, they do not contribute to improvement in sensitivity of a photodetector).

Meanwhile, the inventors of this application have so far assumed metal nanostructures as generation sources of a localized inhomogeneous electric field. However, as a result of further research, the inventors of this application have ascertained that any scatterer can be used as a generation source of a localized inhomogeneous electric field without being limited to a metal nanostructure as long as it can scatter incident light. Here, examples of a scatterer include a dielectric nanostructure of SiO₂, SiN, or the like, and a semiconductor microstructure of amorphous Si or porous Si. Hence, the inventors of this application have obtained knowledge that detection sensitivity can be improved while occurrence of a dark current is curbed if a scatterer can be disposed in a semiconductor layer without performing processing by etching with respect to the semiconductor layer and have completed a photodetector according to the present disclosure.

A photodetector according to an aspect of the present disclosure includes a first conduction-type semiconductor layer, a semiconductor light absorption layer provided on the first conduction-type semiconductor layer, and a second conduction-type semiconductor layer provided on the semiconductor light absorption layer. Inside the semiconductor light absorption layer, finely modified portions forming a localized inhomogeneous electric field inside the semiconductor light absorption layer by scattering incident light are provided in a manner of being separated from the second conduction-type semiconductor layer.

In this photodetector, the finely modified portions are provided inside the semiconductor light absorption layer, and incident light is scattered by the finely modified portions to form a localized inhomogeneous electric field. Accordingly, the generation position of the localized inhomogeneous electric field and the position of a depletion layer in the semiconductor light absorption layer can coincide with or be close to each other, and thus the effect of the localized inhomogeneous electric field in the semiconductor light absorption layer can be sufficiently exhibited. Therefore, improvement in detection sensitivity can be achieved. In addition, in this photodetector, since the finely modified portions are used, etching from the front surface of the semiconductor light absorption layer to the position of the depletion layer is no longer necessary. For this reason, occurrence of the flaw in the semiconductor layer caused by etching near the position of the depletion layer can be avoided, and thus generation of the dark current can be curbed.

The finely modified portions may be arrayed in an intersection direction intersecting a lamination direction of the semiconductor light absorption layer with respect to the first conduction-type semiconductor layer. According to this constitution, a localized inhomogeneous electric field can be widely formed in a direction in which the semiconductor light absorption layer extends. Therefore, a light receiving surface with respect to incident light can be sufficiently secured.

The finely modified portions may be arrayed in a plurality of stages in a lamination direction of the semiconductor light absorption layer with respect to the first conduction-type semiconductor layer. According to this constitution, a localized inhomogeneous electric field can be formed deeply in a thickness direction of the semiconductor light absorption layer. Therefore, even when the position of the depletion layer is widely present in the lamination direction in the semiconductor light absorption layer, the generation position of a localized inhomogeneous electric field and the position of the depletion layer in the semiconductor light absorption layer can more reliably coincide with or be close to each other. In addition, since a non-modified portion is positioned between the finely modified portions in a plurality of stages, a strength of the semiconductor light absorption layer can also be sufficiently maintained.

The finely modified portions may be surrounded by the semiconductor light absorption layer. According to this constitution, the entire parts around the finely modified portions can contribute to formation of a localized inhomogeneous electric field. In addition, since the non-modified portion is positioned around the finely modified portions, the strength of the semiconductor light absorption layer can also be sufficiently maintained.

The finely modified portions may be constituted of at least either modified portions or cavity portions. In this case, incident light can be scattered by the finely modified portions with high efficiency. Therefore, the effect of a localized inhomogeneous electric field in the semiconductor light absorption layer can be further enhanced.

Widths of the finely modified portions in the intersection direction intersecting a lamination direction of the semiconductor light absorption layer with respect to the first conduction-type semiconductor layer may be equal to or shorter than a wavelength of the incident light. According to this constitution, scattered light caused by incident light can be favorably generated in the vicinity of a boundary surface between the finely modified portions and the semiconductor light absorption layer. Therefore, the effect of a localized inhomogeneous electric field in the semiconductor light absorption layer can be further enhanced.

The photodetector may further include an extraction electrode provided on the second conduction-type semiconductor layer and extracting a photocurrent generated in the semiconductor light absorption layer due to formation of the localized inhomogeneous electric field. According to this constitution, when a photocurrent generated in the semiconductor light absorption layer is extracted, compared to when the semiconductor light absorption layer and the extraction electrode come into contact with each other, generation of a dark current caused by a Schottky junction can be curbed.

The finely modified portions may be positioned in a region not overlapping the extraction electrode when viewed in a lamination direction of the semiconductor light absorption layer with respect to the first conduction-type semiconductor layer. In this case, since a situation in which incident light toward the finely modified portions is blocked by the extraction electrode is curbed, a light receiving area with respect to incident light can be sufficiently secured. In addition, in the semiconductor light absorption layer, since the non-modified portion is positioned immediately below the extraction electrode, the strength of the semiconductor light absorption layer can also be sufficiently maintained.

### BRIEF DESCRIPTION OF THE DRAWINGS

FIG. 1 is a schematic cross-sectional view illustrating a constitution of a photodetector according to an embodiment of the present disclosure.

FIG. 2 is a schematic plan view of the photodetector illustrated in FIG. 1.

FIG. 3 is a schematic cross-sectional view illustrating finely modified portions of the photodetector illustrated in FIG. 1.

FIG. 4 is a schematic cross-sectional view illustrating a technique of forming finely modified portions.

FIG. 5 is a schematic cross-sectional view illustrating a constitution of a photodetector according to a modification example.

FIG. 6 is a schematic cross-sectional view illustrating finely modified portions of the photodetector illustrated in FIG. 5.

### DETAILED DESCRIPTION

Hereinafter, with reference to the drawings, a preferred embodiment of a photodetector according to an aspect of the present disclosure will be described in detail.

In the embodiment and the drawings of the photodetector described below, one constituent unit of an incident region of incident light (detection target) is illustrated as a main part. In an actual photodetector, the constituent units may be arrayed at a predetermined pitch.

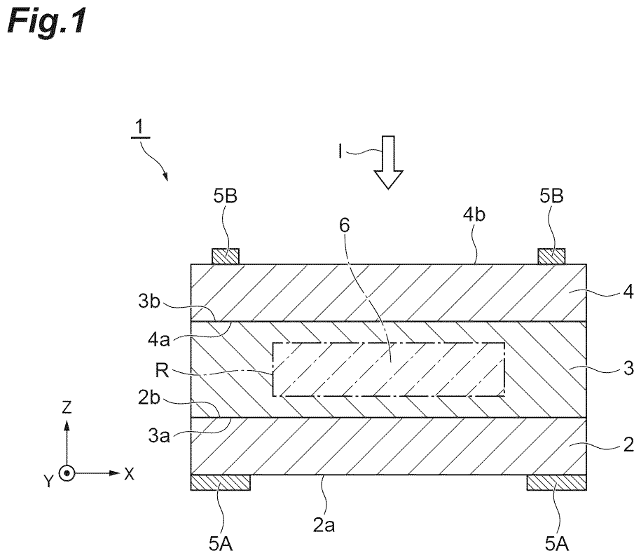

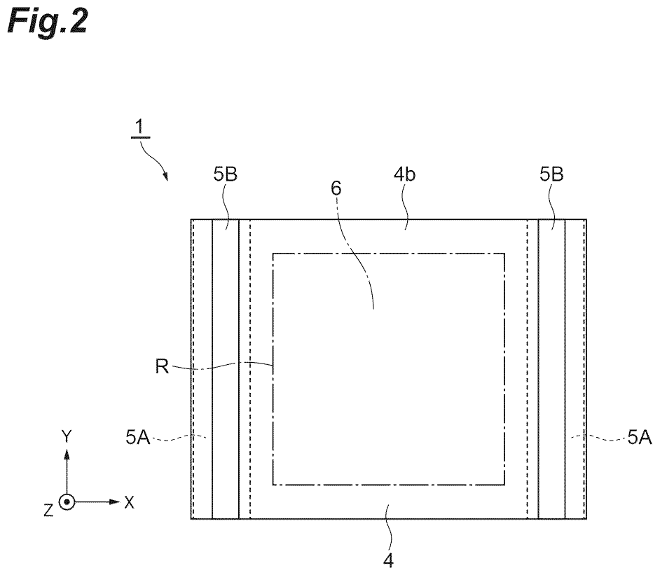

FIG. 1 is a schematic cross-sectional view illustrating a constitution of the photodetector according to the embodiment of the present disclosure. FIG. 2 is a plan view thereof. As illustrated in the same diagram, a photodetector 1 is constituted to include a first conduction-type semiconductor layer 2, a semiconductor light absorption layer 3, a second conduction-type semiconductor layer 4, a pair of extraction electrodes 5A and 5A, and a pair of extraction electrodes 5B and 5B.

In the present embodiment, for the sake of description, the first conduction-type semiconductor layer 2 side is defined as a rear surface of the photodetector 1, and the second conduction-type semiconductor layer 4 side is defined as a front surface of the photodetector 1. The photodetector of the present disclosure may be any of a front surface incidence-type detector and a rear surface incidence-type detector. In the example of FIG. 1, the photodetector 1 is a front surface incidence-type detector in which incident light I is incident from the front surface.

In addition, in the present embodiment, for the sake of description, an X axis, a Y axis, and a Z axis orthogonal to each other will be defined. The Z axis is an axis extending in a lamination direction of the first conduction-type semiconductor layer 2, the semiconductor light absorption layer 3, and the second conduction-type semiconductor layer 4, that is, a lamination direction of the semiconductor light absorption layer 3 with respect to the first conduction-type semiconductor layer 2. The X axis and the Y axis are axes extending in an intersection direction intersecting the lamination direction described above. The X axis lies in a direction in which the extraction electrodes 5A and 5A are connected to each other and the extraction electrodes 5B and 5B are connected to each other. The Y axis lies in an extending direction of each of the extraction electrodes 5A and 5A and the extraction electrodes 5B and 5B.

In the photodetector 1, when light having a wavelength longer than the cutoff wavelength (a wavelength of light having bandgap energy) of a semiconductor is incident as the incident light I, scattered light is generated due to the incident light I. Further, a localized inhomogeneous electric field is generated due to the generated scattered light. In the photodetector 1, direct optical transition inside a semiconductor can be performed utilizing an effect of a localized inhomogeneous electric field, and thus sufficient light can be absorbed inside the semiconductor. In the photodetector 1, when light absorbed inside the semiconductor is extracted to the outside as a photocurrent, photodetection of a wavelength longer than the cutoff wavelength of the semiconductor can be realized. Here, on the assumption that the wavelength of the incident light I (detection target) is near 1,200 nm, dimensions and the like of each of the constituent elements of the photodetector 1 will be described as an example.

The first conduction-type semiconductor layer 2 is made of Si whose conduction type is n-type, for example, and is constituted of a low-resistance semiconductor (n+) having a high carrier concentration. The first conduction-type semiconductor layer 2 exhibits a rectangular shape when viewed in the lamination direction (refer to FIG. 2). The first conduction-type semiconductor layer 2 has a first surface 2a and a second surface 2b opposite to the first surface 2a. The first surface 2a is a surface facing the rear surface of the photodetector 1, and the second surface 2b is a surface facing the front surface of the photodetector 1. A thickness of the first conduction-type semiconductor layer 2 is 1 μm to 50 μm, for example.

The semiconductor light absorption layer 3 is made of Si whose conduction type is p-type, for example, and is constituted of a high-resistance semiconductor (p−) having a low carrier concentration. The semiconductor light absorption layer 3 exhibits a rectangular shape when viewed in the lamination direction. The semiconductor light absorption layer 3 has a first surface 3a and a second surface 3b opposite to the first surface 3a. The first surface 3a is a surface facing the rear surface of the photodetector 1, and the second surface 3b is a surface facing the front surface of the photodetector 1.

The semiconductor light absorption layer 3 is provided such that the entire second surface 2b of the first conduction-type semiconductor layer 2 is covered. On a boundary surface between the semiconductor light absorption layer 3 and the first conduction-type semiconductor layer 2, a pn junction of the semiconductor is formed. A thickness of the semiconductor light absorption layer 3 is determined in accordance with the carrier concentrations of the first conduction-type semiconductor layer 2 and the semiconductor light absorption layer 3. In the present embodiment, the thickness of the semiconductor light absorption layer 3 is 50 nm to 100 μm, for example.

The second conduction-type semiconductor layer 4 is made of Si whose conduction type is p-type, for example, and is constituted of a low-resistance semiconductor (p+) having a high carrier concentration. The second conduction-type semiconductor layer 4 exhibits a rectangular shape when viewed in the lamination direction. The second conduction-type semiconductor layer 4 has a first surface 4a and a second surface 4b opposite to the first surface 4a. A thickness of the second conduction-type semiconductor layer 4 is 100 nm to 1,000 nm, for example.

The extraction electrodes 5A and 5B are electrodes extracting a photocurrent generated in the semiconductor light absorption layer 3 due to formation of a localized inhomogeneous electric field. The extraction electrode 5A is an electrode layer functioning as a cathode of the photodetector 1. The extraction electrode 5A is provided on the first surface 2a of the first conduction-type semiconductor layer 2. The extraction electrode 5A exhibits a rectangular shape when viewed in the lamination direction. The extraction electrode 5A linearly extends in one direction (here, the Y axis direction) in an in-plane direction on the first surface 2a at a position overlapping the second conduction-type semiconductor layer 4, for example, across the first surface 2a of the first conduction-type semiconductor layer 2 from one side to the other side (refer to FIG. 2).

The extraction electrode 5A is formed of a metal such as aluminum (Al), titanium (Ti), or indium (In), for example. The extraction electrode 5A may be constituted using a compounded material including these metals. The extraction electrode 5A may be constituted of a plurality of layers without being limited to a single layer.

The extraction electrode 5B is an electrode functioning as an anode of the photodetector 1. The extraction electrode 5B is provided on the second surface 4b of the second conduction-type semiconductor layer 4. The extraction electrode 5B is disposed in a manner of being separated from the semiconductor light absorption layer 3 and is disposed in a manner of being sufficiently separated with respect to finely modified portions 6 (which will be described below). Similar to the extraction electrode 5A, the extraction electrode 5B exhibits a rectangular shape when viewed in the lamination direction. The extraction electrode 5B linearly extends in one direction (here, the Y axis direction) in the in-plane direction on the second surface 4b across the second surface 4b of the second conduction-type semiconductor layer 4 from one side to the other side (refer to FIG. 2).

The extraction electrode 5B is formed of a metal such as gold (Au), aluminum (Al), or platinum (Pt), for example. The extraction electrode 5B may be constituted using a compounded material including these metals. The extraction electrode 5B may be constituted of a plurality of layers without being limited to a single layer.

Subsequently, a constitution of the semiconductor light absorption layer 3 described above will be described in more detail.

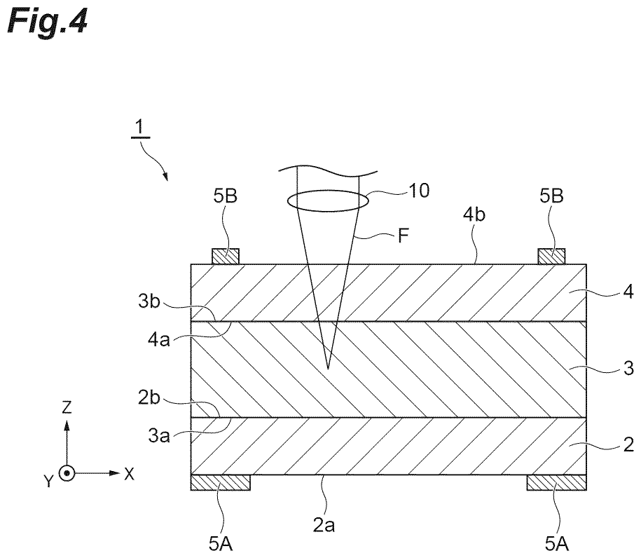

As illustrated in FIG. 1, inside the semiconductor light absorption layer 3, the finely modified portions 6 forming a localized inhomogeneous electric field inside the semiconductor light absorption layer 3 by scattering the incident light I are provided. The finely modified portions 6 are formed by modifying the semiconductor light absorption layer 3 constituted using Si with a laser beam F (refer to FIG. 4). The finely modified portions 6 are arrayed in the intersection direction intersecting the lamination direction of the semiconductor light absorption layer 3 with respect to the first conduction-type semiconductor layer 2.

In the present embodiment, the finely modified portions 6 are arrayed in a latticed shape in the X axis direction and the Y axis direction which are the in-plane direction of the first surface 3a and the second surface 3b of the semiconductor light absorption layer 3. The finely modified portions 6 and 6 adjacent to each other in the X axis direction and the Y axis direction are separated with a predetermined gap therebetween. Therefore, a part around each of the finely modified portions 6 is in a state of being surrounded by the semiconductor light absorption layer 3 which is a non-modified portion not affected by modification using the laser beam F.

As illustrated in FIG. 2, an array region R in which the finely modified portions 6 are arrayed exhibits a rectangular shape when viewed in the lamination direction. The array region R is positioned on an inward side of the extraction electrodes 5B and 5B in the X axis direction. That is, the array region R is positioned in a region sandwiched between the extraction electrodes 5B and 5B in the X axis direction. Accordingly, each of the finely modified portions 6 positioned in the array region R is positioned in a region not overlapped by the extraction electrodes 5B and 5B when viewed in the lamination direction.

Due to such a constitution, a situation in which the incident light I from the front surface side of the photodetector 1 toward the semiconductor light absorption layer 3 is blocked by the extraction electrodes 5B and 5B can be curbed. When the photodetector 1 is a rear surface incidence-type photodetector, the array region R in which the finely modified portions 6 are arrayed need only be positioned on the inward side of the extraction electrodes 5A and 5A in the X axis direction. Accordingly, a situation in which the incident light I from the rear surface side of the photodetector 1 toward the semiconductor light absorption layer 3 is blocked by the extraction electrodes 5A and 5A can be curbed.

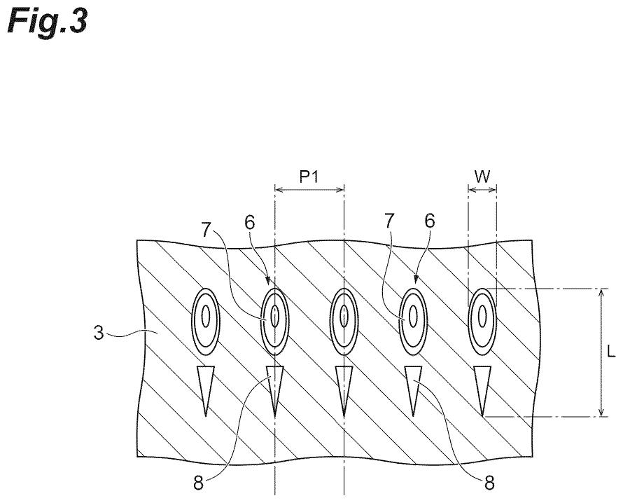

The finely modified portions 6 are constituted of at least one of modified portions 7 and cavity portions 8. In the present embodiment, as illustrated in FIG. 3, one finely modified portion 6 is constituted of a set of one modified portion 7 and one cavity portion 8 as a unit. In the present embodiment, in each of the finely modified portions 6, the modified portion 7 and the cavity portion 8 are in a state of being arranged in the lamination direction. The modified portion 7 is positioned on the second surface 3b side of the semiconductor light absorption layer 3, and the cavity portion 8 is positioned on the first surface 3a side of the semiconductor light absorption layer 3.

In each of the finely modified portions 6, the modified portion 7 and the cavity portion 8 may come into contact with each other in the lamination direction or may be separated from each other in the lamination direction. When the modified portion 7 and the cavity portion 8 are separated from each other in the lamination direction, each of the modified portion 7 and the cavity portion 8 is in a state of being surrounded by the semiconductor light absorption layer 3 which is a non-modified portion not affected by modification using the laser beam F.

Each of the modified portion 7 and the cavity portion 8 functions as a scatterer scattering the incident light I. The modified portion 7 is constituted using amorphous Si, for example. This amorphous Si is formed when Si constituting the semiconductor light absorption layer 3 is modified using the laser beam F. The cavity portion 8 is formed when Si constituting the semiconductor light absorption layer 3 is eliminated due to the laser beam F. When the array region R in which the finely modified portions 6 are arrayed is viewed in its entirety, the cavity portion 8 of each of the finely modified portions 6 forms a porous Si structure inside the semiconductor light absorption layer 3.

Lengths L of the finely modified portions 6 in the lamination direction are adjusted in accordance with a range of a position of a depletion layer in the semiconductor light absorption layer 3. Here, the length L is a length including the modified portion 7 and the cavity portion 8. That is, the length L is a length from an end of the modified portion 7 on the second surface 3b side to an end of the cavity portion 8 on the first surface 3a side. As an example, the length L is approximately 1 μm to 20 μm.

Widths W of the finely modified portions 6 in the intersection direction are equal to or shorter than the wavelength of the incident light I. Here, the width W is a width of a part where widths of the modified portion 7 and the cavity portion 8 in the intersection direction are maximized. In the present embodiment, the wavelength of the incident light I is near 1,200 nm, and the width W is approximately several hundred nm to 1,000 nm.

An array pitch P1 of the finely modified portions 6 in the intersection direction is adjusted in consideration of a balance between a function as scatterers with respect to the incident light I and a strength of the semiconductor light absorption layer 3. Here, the array pitch P1 is a length from the center position of one finely modified portion 6 to the center position of another finely modified portion 6 adjacent to the one finely modified portion 6. As an example, the array pitch P1 is approximately 1 μm to 50 μm.

As illustrated in FIG. 4, the finely modified portions 6 described above can be formed using a laser processing technology of two-photon absorption, for example. In the example of FIG. 4, irradiation is performed with the laser beam F from the front surface of the photodetector 1, that is, the second surface 4b side of the second conduction-type semiconductor layer 4 toward the semiconductor light absorption layer 3. The laser beam F used for processing need only be a laser beam having a wavelength with optical transparency with respect to Si constituting the semiconductor light absorption layer 3. Regarding the laser beam F, for example, an Nd:YAG laser (wavelength: 1,064 nm) can be used.

By focusing the laser beam F using a lens 10, only a target position in the semiconductor light absorption layer 3 can be modified without affecting the second conduction-type semiconductor layer 4 by modification using the laser beam F. A plurality of finely modified portions 6 are formed in the array region R by scanning an irradiation position of the laser beam F set in advance in the array region R in the X axis direction and the Y axis direction.

Irradiation conditions of the laser beam F are suitably adjusted in accordance with dimensions, depths, and the like of the finely modified portions 6 to be formed. As an example, the irradiation conditions of the laser beam F are set as follows.
Output: 100 ILO/pulse
Pulse width: tens of ns to hundreds of ns
Repetition frequency: 100 kHz
Light focusing spot size: 3.14×10⁻⁸ cm²
Polarization state: linear polarization

As described above, in the photodetector 1, the finely modified portions 6 are provided inside the semiconductor light absorption layer 3, and the incident light I is scattered by the finely modified portions 6 to form a localized inhomogeneous electric field. Accordingly, a generation position of a localized inhomogeneous electric field and a position of the depletion layer in the semiconductor light absorption layer 3 can coincide with or be close to each other, and thus the effect of a localized inhomogeneous electric field in the semiconductor light absorption layer 3 can be sufficiently exhibited. Therefore, in the photodetector 1, improvement in detection sensitivity can be achieved. In addition, in the photodetector 1, since the finely modified portions 6 are used, etching from a front surface of the semiconductor light absorption layer 3 to the position of the depletion layer is no longer necessary. For this reason, occurrence of defects in a semiconductor layer caused by etching near the position of the depletion layer can be avoided, and thus generation of a dark current can be curbed.

In the present embodiment, a laser processing technology of two-photon absorption is used for forming the finely modified portions 6. For this reason, no complicated semiconductor processing technology, such as nano-patterning or dry etching, is necessary, and thus simplification of manufacturing steps of the photodetector 1 can be achieved. This also contributes to improvement in manufacturing yield of the photodetector 1. In addition, in the photodetector 1, scatterers are formed by the finely modified portions 6, and thus use of metal can be omitted except for the extraction electrodes 5A and 5B. Therefore, an absorption loss of the incident light I due to metal can be favorably curbed, and reduction in manufacturing costs of the photodetector 1 can be achieved.

In the photodetector 1, the finely modified portions 6 are arrayed in the intersection direction intersecting the lamination direction of the semiconductor light absorption layer 3 with respect to the first conduction-type semiconductor layer 2. Accordingly, a localized inhomogeneous electric field can be widely formed in the X axis direction and the Y axis direction in which the semiconductor light absorption layer 3 extends. Therefore, a light receiving area with respect to the incident light I can be sufficiently secured.

In the photodetector 1, the finely modified portions 6 are surrounded by the semiconductor light absorption layer 3. Accordingly, the entire parts around the finely modified portions 6 can contribute to formation of a localized inhomogeneous electric field. In addition, since the non-modified portion not affected by modification using the laser beam F is positioned around the finely modified portions 6, the strength of the semiconductor light absorption layer 3 can also be sufficiently maintained.

In the photodetector 1, the finely modified portions 6 are constituted of the modified portions 7 and the cavity portions 8. Accordingly, the incident light I can be scattered by the finely modified portions 6 with high efficiency. Therefore, the effect of a localized inhomogeneous electric field in the semiconductor light absorption layer 3 can be further enhanced.

In the photodetector 1, widths W of the finely modified portions 6 in the intersection direction are equal to or shorter than the wavelength of the incident light I. Accordingly, the scattered light caused by incident light I can be favorably generated in the vicinity of a boundary surface between the finely modified portions 6 and the semiconductor light absorption layer 3. Therefore, the effect of a localized inhomogeneous electric field in the semiconductor light absorption layer 3 can be further enhanced.

In the photodetector 1, the extraction electrodes 5B extracting a photocurrent generated in the semiconductor light absorption layer 3 due to formation of a localized inhomogeneous electric field are provided on the second conduction-type semiconductor layer 4. According to this constitution, when a photocurrent generated in the semiconductor light absorption layer 3 is extracted, compared to when the semiconductor light absorption layer 3 and the extraction electrodes 5B come into contact with each other, generation of a dark current caused by a Schottky junction can be curbed.

In the photodetector 1, the finely modified portions 6 are positioned in a region not overlapping the extraction electrodes 5B when viewed in the lamination direction. According to such a constitution, since a situation in which the incident light I toward the finely modified portions 6 is blocked by the extraction electrodes 5B is curbed, the light receiving surface with respect to the incident light I can be sufficiently secured. In addition, in the semiconductor light absorption layer 3, since the non-modified portion of the semiconductor light absorption layer 3 is positioned immediately below the extraction electrodes 5B, the strength of the semiconductor light absorption layer 3 can also be sufficiently maintained.

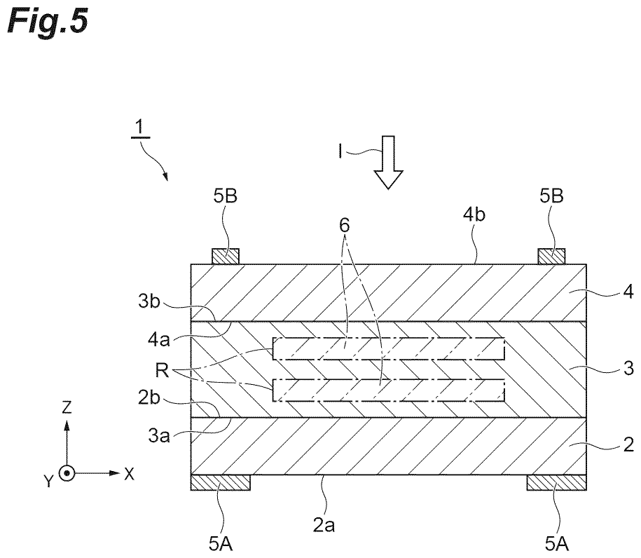

The present disclosure is not limited to the foregoing embodiment. For example, as illustrated in FIG. 5, the finely modified portions 6 may be arrayed in a plurality of stages in the lamination direction of the semiconductor light absorption layer 3 with respect to the first conduction-type semiconductor layer 2. In the example of FIG. 5, the finely modified portions 6 are arrayed in two stages with a predetermined gap therebetween in the lamination direction. The finely modified portions 6 may be arrayed in three or more stages with a predetermined gap therebetween in the lamination direction. A non-modified portion not affected by modification using the laser beam F is positioned between the array regions R and R in which the finely modified portions 6 are arrayed.

According to such a constitution, a localized inhomogeneous electric field can be formed deeply in a thickness direction of the semiconductor light absorption layer 3. Therefore, even when the position of the depletion layer is widely present in the lamination direction in the semiconductor light absorption layer 3, the generation position of a localized inhomogeneous electric field and the position of the depletion layer in the semiconductor light absorption layer 3 can more reliably coincide with or be close to each other. In addition, since a non-modified portion is positioned between the finely modified portions 6 and 6 in a plurality of stages, the strength of the semiconductor light absorption layer 3 can also be sufficiently maintained.

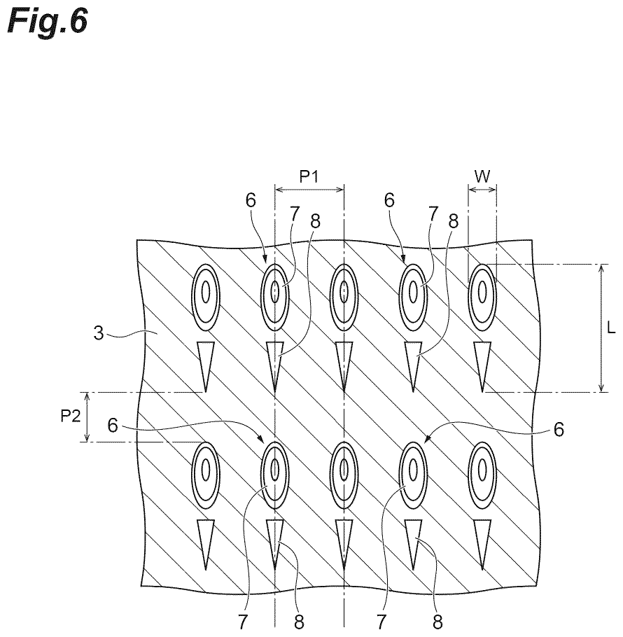

An array pitch P2 of the finely modified portions 6 in the lamination direction is adjusted in consideration of a balance between the function as scatterers with respect to the incident light I and the strength of the semiconductor light absorption layer 3. Here, as illustrated in FIG. 6, the array pitch P2 is a length from an end of the cavity portion 8 of the finely modified portion 6 on the first surface 3a side in one array region R to an end of the modified portion 7 of the finely modified portion 6 on the second surface 3b side in another array region R. The array pitch P2 may be approximately one time to five times the lengths L of the finely modified portions 6 in the lamination direction, for example.

Similar to the foregoing embodiment, a laser processing technology of two-photon absorption can be used for forming the finely modified portions 6 in a plurality of stages. In addition, it is favorable to combine a multi-point laser processing technology using a spatial light modulator (SLM) with the laser processing technology. In this case, the finely modified portions 6 in a plurality of stages can be formed by performing scanning once with the laser beam F, and thus complicated manufacturing steps of the photodetector 1 can be avoided.

In the foregoing embodiment, a constitution in which the finely modified portions 6 are arrayed in a latticed shape when viewed in the lamination direction has been described as an example, but the array of the finely modified portions 6 is not limited to this. For example, the finely modified portions 6 may be arrayed in a zigzag shape when viewed in the lamination direction or may be randomly arrayed. The array region R in which the finely modified portions 6 are arrayed may not necessarily have a rectangular shape when viewed in the lamination direction. The array region R may have a different shape such as a circular shape, an elliptical shape, a triangular shape, or a polygonal shape when viewed in the lamination direction.

In the foregoing embodiment, the finely modified portions 6 are constituted of both the modified portions 7 and the cavity portions 8, but the finely modified portions 6 may be constituted of any one of the modified portions 7 and the cavity portions 8. In addition, in the foregoing embodiment, when the finely modified portions 6 are formed, irradiation is performed with the laser beam F from the second surface 4b side of the second conduction-type semiconductor layer 4 toward the semiconductor light absorption layer 3, but irradiation may be performed with the laser beam F from the first surface 2a side of the first conduction-type semiconductor layer 2 toward the semiconductor light absorption layer 3. In this case, a positional relationship between the modified portions 7 and the cavity portions 8 in the finely modified portions 6 is reversed from that in FIG. 3. Moreover, in the foregoing embodiment, each of the semiconductor layers has been described as an example while having the first conduction type as n-type and the second conduction type as p-type, but the first conduction type may be the p-type and the second conduction type may be the n-type.

What is claimed is:

1. A photodetector comprising:
a first conduction-type semiconductor layer;
a semiconductor light absorption layer provided on the first conduction-type semiconductor layer; and
a second conduction-type semiconductor layer provided on the semiconductor light absorption layer,
wherein inside the semiconductor light absorption layer, finely modified portions forming a localized inhomogeneous electric field inside the semiconductor light absorption layer by scattering incident light are provided in a manner of being separated from the second conduction-type semiconductor layer.

2. The photodetector according to claim 1,
wherein the finely modified portions are arrayed in an intersection direction intersecting a lamination direction of the semiconductor light absorption layer with respect to the first conduction-type semiconductor layer.

3. The photodetector according to claim 1,
wherein the finely modified portions are arrayed in a plurality of stages in a lamination direction of the semiconductor light absorption layer with respect to the first conduction-type semiconductor layer.

4. The photodetector according to claim 1,
wherein the finely modified portions are surrounded by the semiconductor light absorption layer.

5. The photodetector according to claim 1,
wherein the finely modified portions are constituted of at least either modified portions or cavity portions.

6. The photodetector according to claim 1,
wherein widths of the finely modified portions in the intersection direction intersecting a lamination direction of the semiconductor light absorption layer with respect to the first conduction-type semiconductor layer are equal to or shorter than the wavelength of the incident light.

7. The photodetector according to claim 1 further comprising:
an extraction electrode provided on the second conduction-type semiconductor layer and extracting photocurrent generated in the semiconductor light absorption layer due to formation of the localized inhomogeneous electric field.

8. The photodetector according to claim 7,
wherein the finely modified portions are positioned in a region not overlapping the extraction electrode when viewed in a lamination direction of the semiconductor light absorption layer with respect to the first conduction-type semiconductor layer.
